(19) United States
(12) Patent Application Publication
(10) Pub. No.: US 2026/0122817 A1
(43) Pub. Date: Apr. 30, 2026

(54) REMOVAL ASSEMBLY, FIXING FRAME AND ELECTRONIC DEVICE

(71) Applicant: WISTRON CORP., New Taipei City (TW)

(72) Inventor: WEI FAN LIN, New Taipei City (TW)

(21) Appl. No.: 19/013,049

(22) Filed: Jan. 8, 2025

(30) Foreign Application Priority Data
Oct. 25, 2024 (TW) 113140733

(51) Int. Cl. H05K 7/14

(52) U.S. Cl. CPC H05K 7/1409; H05K 7/1405; H05K 7/1461

(57) ABSTRACT

This disclosure provides a removal assembly configured to remove an interface card which is slidably placed into a guiding element. The removal assembly includes a sliding element, a lifted element and a pushing element. The sliding element is configured to be movably disposed on the guiding element along a first direction. The lifted element is movably disposed on the sliding element along a second direction different from the first direction. The pushing element is movably disposed in the sliding element along the first direction so as to selectively move the lifted element into a recess of the interface card.

### CROSS-REFERENCE TO RELATED APPLICATIONS

This non-provisional application claims priority under 35 U.S.C. § 119 (a) on Patent Application No(s). 113140733 filed in Taiwan on Oct. 25, 2024, the entire contents of which are hereby incorporated by reference.

### TECHNICAL FIELD

The present disclosure relates to a removal assembly, a fixing frame and an electronic device, more particularly to a removal assembly, a fixing frame and an electronic device including the same for easy removal of an interface card.

### BACKGROUND

With the popularity of the open compute project (OCP), electronic products compliant with the OCP specifications are more widely utilized now, such as OCP interface cards. Generally, in order to compactly arrange components in an internal space of an electronic device such as a server, there is no release structure particularly provided in the internal space for facilitating the removal of the OCP interface card.

Therefore, some parts of the OCP interface card having relatively high structural strength, such as heat dissipation fins, are held by fingers during the removal of the OCP interface card. However, holding these parts of the OCP interface card for the removal may easily damage the OCP interface card and thus cause the OCP interface card unable to be used again, and may even scratch the user's finger.

### SUMMARY

The present disclosure provides a removal assembly, a fixing frame and an electronic device for achieving easy removal of an interface card.

According to one aspect of the present disclosure, a removal assembly configured to remove an interface card which is slidably placed into a guiding element includes a sliding element, a lifted element, and a pushing element. The sliding element is configured to be movably disposed on the guiding element along a first direction. The lifted element is movably disposed on the sliding element along a second direction different from the first direction. The pushing element is movably disposed in the sliding element along the first direction so as to selectively move the lifted element into a recess of the interface card.

According to another aspect of the present disclosure, a fixing frame configured to fix an interface card includes a guiding element and a removal assembly. The guiding element is configured for the interface card to be slidably placed into the guiding element. The removal assembly includes a sliding element, a lifted element and a pushing element. The sliding element is movably disposed on the guiding element along a first direction. The lifted element is movably disposed on the sliding element along a second direction different from the first direction. The pushing element is movably disposed in the sliding element along the first direction so as to selectively move the lifted element into a recess of the interface card.

According to another aspect of the present disclosure, an electronic device includes a mainboard, a connector, a fixing frame and an interface card. The connector is disposed on the mainboard. The fixing frame is located on a side of the connector. The fixing frame includes a guiding element and a removal assembly. The removal assembly includes a sliding element, a lifted element and a pushing element. The sliding element is movably disposed on the guiding element along a first direction. The lifted element is movably disposed on the sliding element along a second direction different from the first direction. The pushing element is movably disposed in the sliding element along the first direction. The interface card is slidably placed into the guiding element and detachably connected to the connector. The pushing element is selectively moves along the first direction so as to move the lifted element into a recess of the interface card.

According to the removal assembly, the fixing frame and the electronic device discussed above, the connection between the interface card and the connector can be released by simple operation. Then, the interface card can be removed simply by holding the interface card. The interface card is not damaged during its removal, ensuring the reusability of the withdrawn interface card.

### BRIEF DESCRIPTION OF THE DRAWINGS

The present disclosure will become more fully understood from the detailed description given hereinbelow and the accompanying drawings which are given by way of illustration only and thus are not intending to limit the present disclosure and wherein:

FIG. 1 is a perspective view of an electronic device according to one embodiment of the present disclosure;

FIG. 2 is a perspective view of a trigger assembly of a fixing frame of the electronic device of FIG. 1;

FIG. 3 is a perspective view of a removal assembly of the fixing frame of the electronic device of FIG. 1;

FIG. 4 is another perspective view of the removal assembly of FIG. 3;

FIG. 5 is an exploded view of the removal assembly of FIG. 3;

FIG. 6 to FIG. 7 show operation of the trigger assembly of FIG. 2;

FIG. 8 to FIG. 13 are partial and cross-sectional views of the electronic device of FIG. 1 during removal of an interface card;

FIG. 14 to FIG. 16 are partial and cross-sectional views of the electronic device of FIG. 1 during insertion of an interface card;

FIG. 17 is a perspective view of an electronic device according to another embodiment of the present disclosure; and

FIG. 18 is a perspective view of an electronic device according to further another embodiment of the present disclosure.

### DETAILED DESCRIPTION

Aspects and advantages of the invention will become apparent from the following detailed descriptions with the accompanying drawings. For purposes of explanation, one or more specific embodiments are given to provide a thorough understanding of the invention, and which are described in sufficient detail to enable one skilled in the art to practice the described embodiments. It should be understood that the following descriptions are not intended to limit the embodiments to one specific embodiment. On the contrary, it is intended to cover alternatives, modifications, and equivalents as can be included within the spirit and scope of the described embodiments as defined by the appended claims.

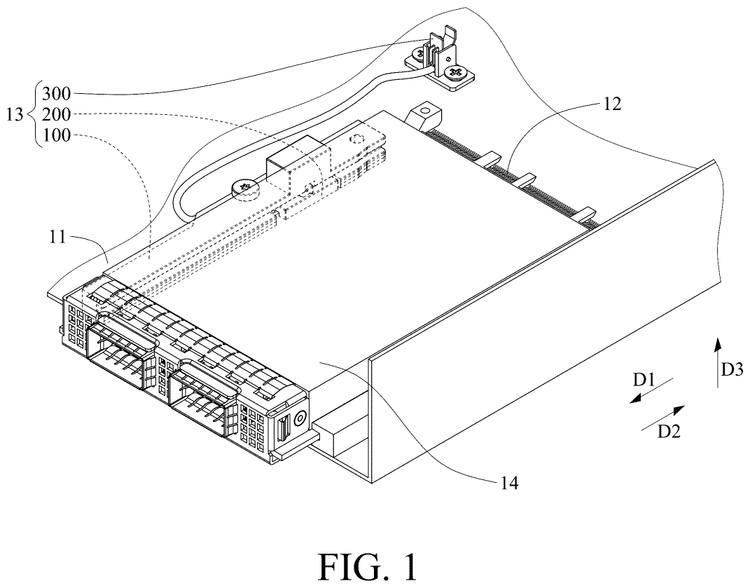

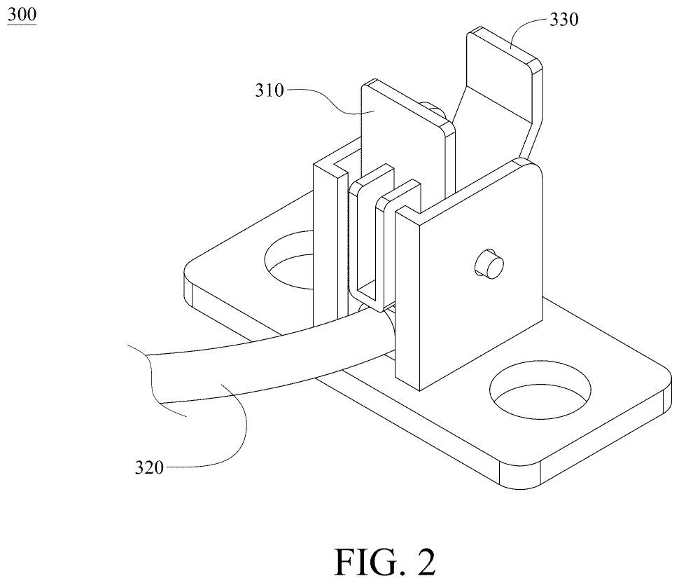

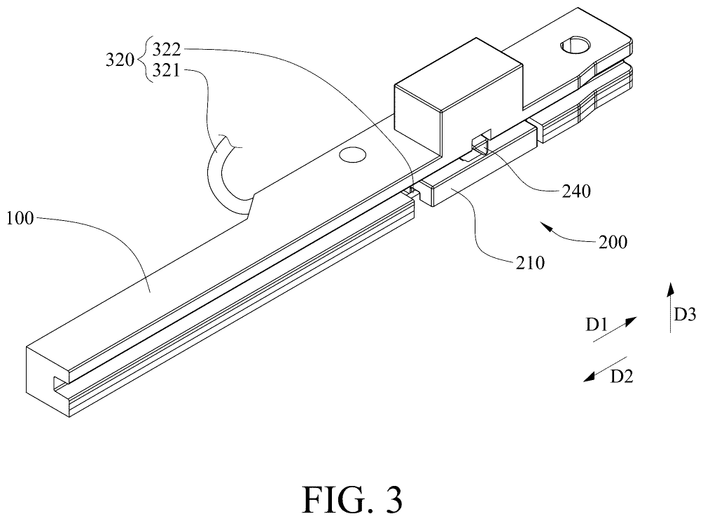

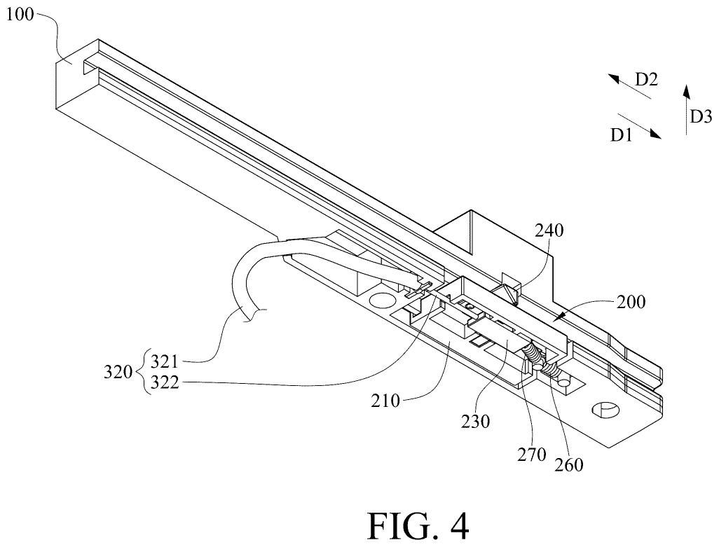

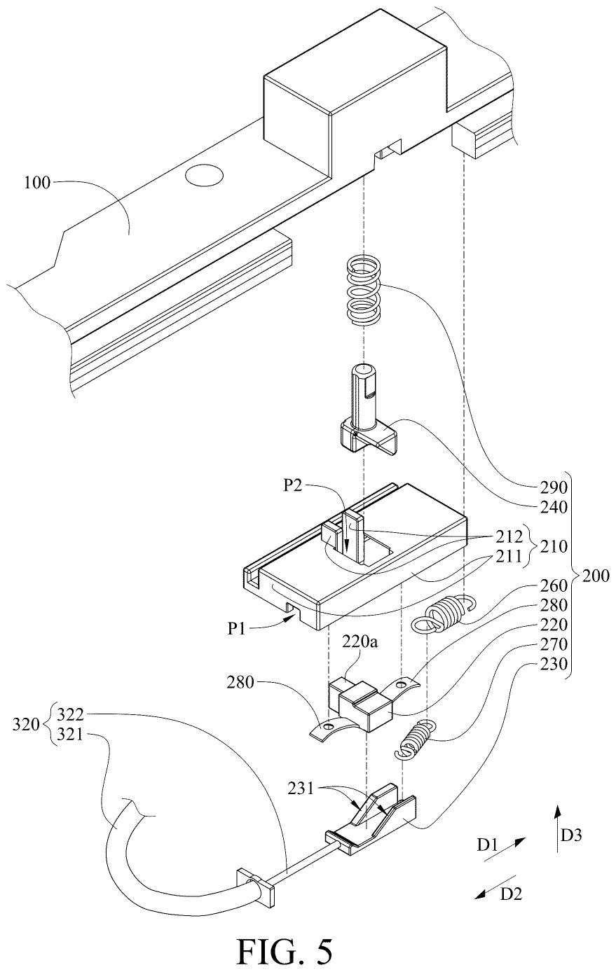

In the following, one embodiment of the present disclosure is illustrated. Please refer to FIG. 1 to FIG. 5, where FIG. 1 is a perspective view of an electronic device according to one embodiment of the present disclosure, FIG. 2 is a perspective view of a trigger assembly of a fixing frame of the electronic device of FIG. 1, FIG. 3 is a perspective view of a removal assembly of the fixing frame of the electronic device of FIG. 1, FIG. 4 is another perspective view of the removal assembly of FIG. 3, and FIG. 5 is an exploded view of the removal assembly of FIG. 3.

An electronic device 1 provided in this embodiment may be, for example, a server. The electronic device 1 includes a mainboard 11, a connector 12, a fixing frame 13 and an interface card 14. The connector 12 is disposed on the mainboard 11 and may be electrically connected to the mainboard 11.

The fixing frame 13 is located on a side of the connector 12. More specific, the fixing frame 13 may be, for example, disposed on the mainboard 11, but the present disclosure is not limited thereto. In some embodiments of the present disclosure, the fixing frame may alternatively be, for example, disposed on a casing of the electronic device. In this embodiment, the fixing frame 13 may include a guiding element 100, a removal assembly 200 and a trigger assembly 300.

The guiding element 100 may be, for example, a sliding rail. The guiding element 100 may correspond to one end of the connector 12, and the guiding element 100 and the connector 12 surround a space for the interface card 14 to be placed. Please be noted that the quantity of the guiding element 100 is not intended to restrict the present disclosure. In some embodiments of the present disclosure, the fixing frame may include two or more guiding elements collaborating with the connector to surround a space for an interface card to be placed.

The removal assembly 200 may include a sliding element 210, a lifted element 220, a pushing element 230, a blocking element 240, a first return element 260, a second return element 270, two third return elements 280 and a fourth return element 290. Please be noted that the quantity of the removal assembly 200 is not intended to restrict the present disclosure. In some embodiments of the present disclosure, the fixing frame may include two or more removal assemblies for corresponding to the quantity of the guiding elements.

The sliding element 210 is movably disposed on the guiding element 100 along an insertion direction D1 and a first direction (which can also be considered as a removal direction) D2 that is opposite to the insertion direction D1. The sliding element 210 may include a plurality of first side walls 211 and a plurality of second side walls 212. The first side walls 211 can surround a horizontal passage P1. The second side walls 212 may be protruded from the first side walls 211 along, for example, a second direction (which can also be considered as a lifting direction) D3 that is perpendicular to the insertion direction D1 and the first direction D2, and the second side walls 212 can surround a vertical passage P2.

The lifted element 220 may have a guiding protrusion 220a movably disposed in the vertical passage P2 of the sliding element 210 along the second direction D3. The lifted element 220 may have a plurality of first inclined guiding surfaces 221. The first inclined guiding surfaces 221 may be located close to the pushing element 230 and may face towards the connector 12 (shown in FIG. 1). Please be noted that the quantity and the positions of the first inclined guiding surfaces 221 are not intended to restrict the present disclosure. In some embodiments of the present disclosure, the lifted element may have only one first inclined guiding surface.

The pushing element 230 may be movably disposed in the horizontal passage P1 of the sliding element 210 along the insertion direction D1 and the first direction D2. The pushing element 230 may have a plurality of second inclined guiding surfaces 231. The second inclined guiding surfaces 231 may be located close to the lifted element 220 and may face away from the connector 12 (shown in FIG. 1). Please be noted that the quantity and positions of the second inclined guiding surfaces 231 are not intended to restrict the present disclosure. In some embodiments of the present disclosure, the pushing element may have only one second inclined guiding surface. In some other embodiments of the present disclosure, there may be only one of the lifted element and the pushing element having one or more inclined guiding surfaces.

The blocking element 240 is movably disposed on the guiding element 100 along the second direction D3. The blocking element 240 may have a blocking surface 241 and an inclined abutted surface 242. The normal direction of the blocking surface 241 may be opposite to the first direction D2. The inclined abutted surface 242 may face away from the blocking surface 241.

The first return element 260 may be, for example, a tension spring. The first return element 260 may be connected to the guiding element 100 and the sliding element 210. The second return element 270 may be, for example, a tension spring. The second return element 270 may be connected to the sliding element 210 and the pushing element 230. The third return elements 280 may be, for example, sheet springs. The third return elements 280 may be connected to two opposite ends of a side of the lifted element 220 close to the pushing element 230. The fourth return element 290 may be a compression spring. The fourth return element 290 may be disposed between the guiding element 100 and the blocking element 240. Please be noted that the quantity of the third return elements 280 is not intended to restrict the present disclosure. In some embodiments of the present disclosure, the fixing frame may include only one third return element.

The trigger assembly 300 may include a base member 310, a connection member 320 and a pivot member 330.

The base member 310 may be, for example, disposed on the mainboard 11 (shown in FIG. 1), but the present disclosure is not limited thereto. In some embodiments of the present disclosure, the base member may be, for example, alternatively disposed on the casing of the electronic device.

The connection member 320 may include a sleeve 321 and a wire 322. The sleeve 321 is sleeved on the wire 322, and two opposite ends of the sleeve 321 can respectively abut on the base member 310 and the guiding element 100. The wire 322 has flexibility, and two opposite ends of the wire 322 can be respectively connected to the pivot member 330 and the pushing element 230.

The pivot member 330 is pivotably disposed on the base member 310. The pivot member 330 may be connected to the connection member 320 for connecting the pushing element 230 via the connection member 320.

The interface card 14 may be compliant with the specification of the open compute project (OCP). The interface card 14 is slidably placed into the guiding element 100 along the insertion direction D1 and detachably connected to the connector 12.

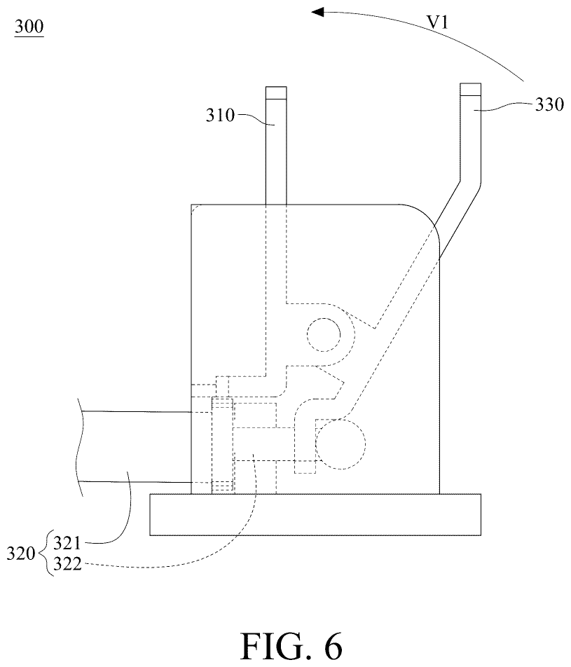

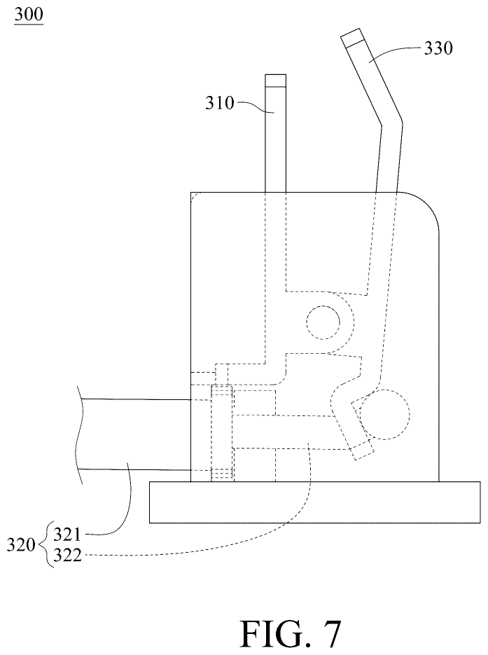

In the following, operation of the electronic device 1 during removal of the interface card 14 is illustrated. Please refer to FIG. 6 to FIG. 7 with reference to FIG. 1 to FIG. 5, where FIG. 6 to FIG. 7 show operation of the trigger assembly of FIG. 2.

In initial, the trigger assembly 300 is not subjected to any external force and is in a state as shown in FIG. 6. The pivot member 330 at the state shown in FIG. 6 can be pivoted by an external force with respect to the base member 310 along a pivot direction V1 to be in a state as shown in FIG. 7. During the pivoting of the pivot member 330, the pivot member 330 can pull the wire 322 to move the wire 322 with respect to the sleeve 321.

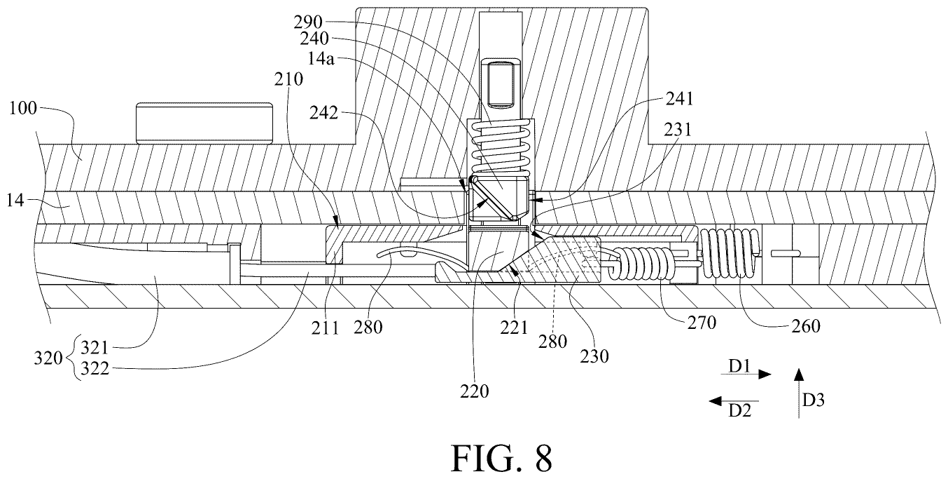

Then, please refer to FIG. 8 to FIG. 13 with reference to FIG. 1 to FIG. 7, where FIG. 8 to FIG. 13 are partial and cross-sectional views of the electronic device of FIG. 1 during removal of an interface card.

In initial, as shown in FIG. 8, the blocking element 240 can be at least partially located in the recess 14a of the interface card 14 so as to restrict movement of the interface card 14 along the first direction D2 via the blocking surface 241.

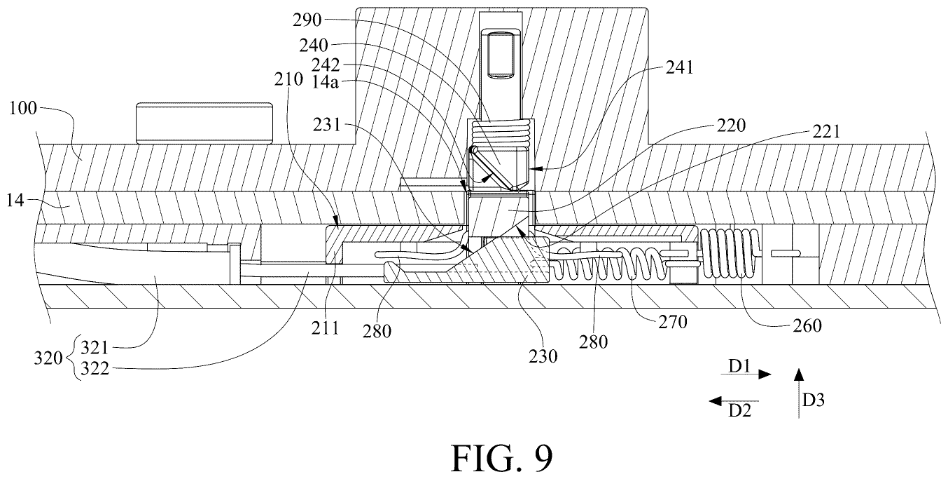

During the pull of the pivot member 330 to enable the movement of the wire 322 with respect to the sleeve 321, the pushing element 230 connected to the wire 322 moves along the first direction D2 from a state shown in FIG. 8 to be in a state shown in FIG. 9. With the guiding between the first inclined guiding surface 221 of the lifted element 220 and the second inclined guiding surface 231 of the pushing element 230, as well as the restriction of the second side walls 212 (shown in FIG. 5), the guiding protrusion 220a (shown in FIG. 5) located in the vertical passage P2 is lifted along the second direction D3, causing the lifted element 220 to be moved into the recess 14a of the interface card 14 along the second direction D3. As such, the lifted element 220 abuts the blocking element 240 to remove the blocking element 240 from the recess 14a.

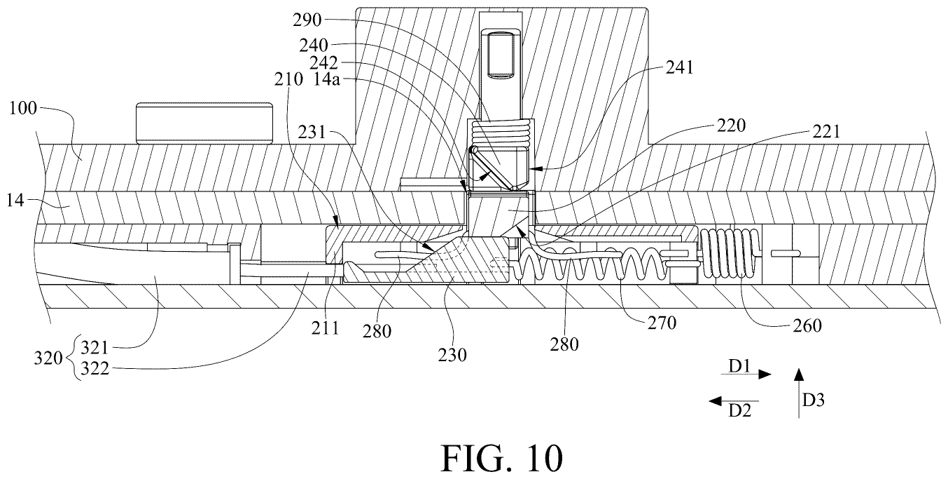

Then, the pushing element 230 in the state shown in FIG. 9 remains pulled by the wire 322, so that the pushing element 230 keeps moving along the first direction D2 to be in a state in which the pushing element 230 abuts on one of the first side walls 211 of the sliding element 210, as shown in FIG. 10.

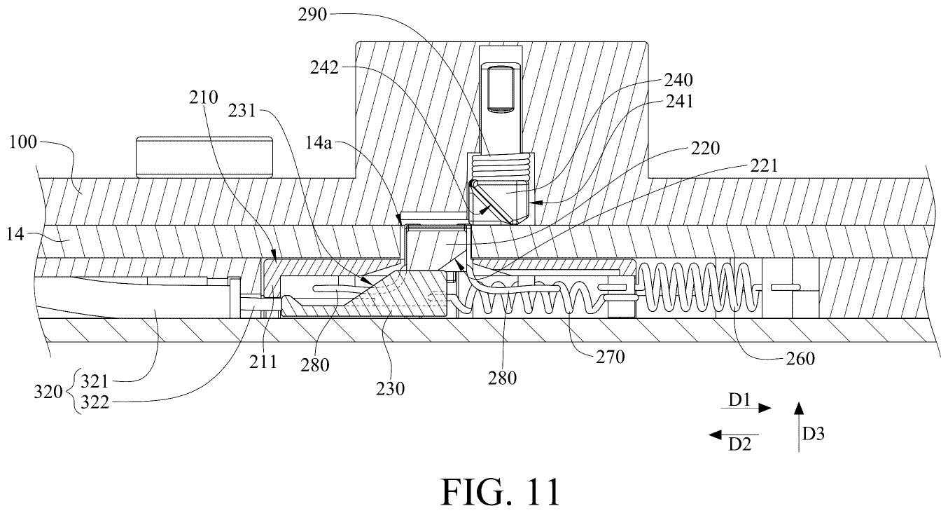

Then, the pushing element 230 is configured to push the sliding element 210 for driving the lifted element 220 to push the interface card 14 along the first direction D2. Specifically, the pushing element 230 which is still pulled by the wire 322 pushes the one of the first side walls 211 along the first direction D2 so as to move the sliding element 210 along the first direction D2 from the state shown in FIG. 10 to the state shown in FIG. 11. During the movement of the sliding element 210 along the first direction D2, the second side walls 212 (shown in FIG. 5) of the sliding element 210 moves the guiding protrusion 220a (shown in FIG. 5) of the lifted element 220 along the first direction D2, with another portion of the lifted element 220 being located in the recess 14a of the interface card 14, so that the lifted element 220 can push the interface card 14 along the first direction D2 to remove the interface card 14 from the connector 12 (shown in FIG. 1). Please be noted that in this state, the blocking element 240 remains lifted since the interface card 14 replaces the lifted element 220 to abut on the blocking element 240.

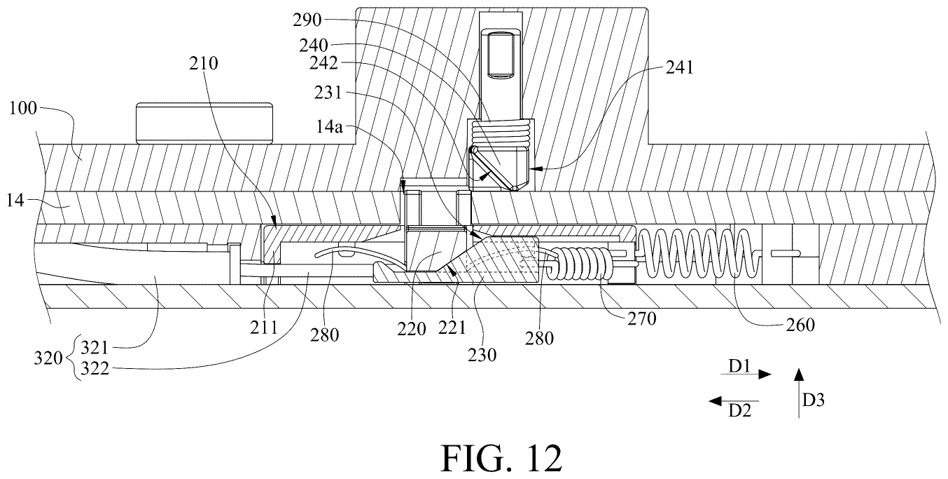

Then, the external force applied on the pivot member 330 can be released. Since the pushing element 230 is not pulled by the pivot member 330 via the wire 322, the second return element 270 connected to the sliding element 210 and the pushing element 230 returns the pushing element 230 along the insertion direction D1 with respect to the sliding element 210. Also, since the lifted element 220 is not pushed by the pushing element 230, the third return elements 280 connected to the lifted element 220 can recover from deformation through its flexibility, such that the lifted element 220 can be moved out of the recess 14a of the interface card 14 to be in a state as shown in FIG. 12.

At this time, there is no element located in the recess 14a to block the movement of the interface card 14, and the interface card 14 is also detached from the connector 12. Therefore, the interface card 14 can be smoothly withdrawn from the guiding element 100 for subsequent process, such as examination, maintenance or replacement of the interface card 14.

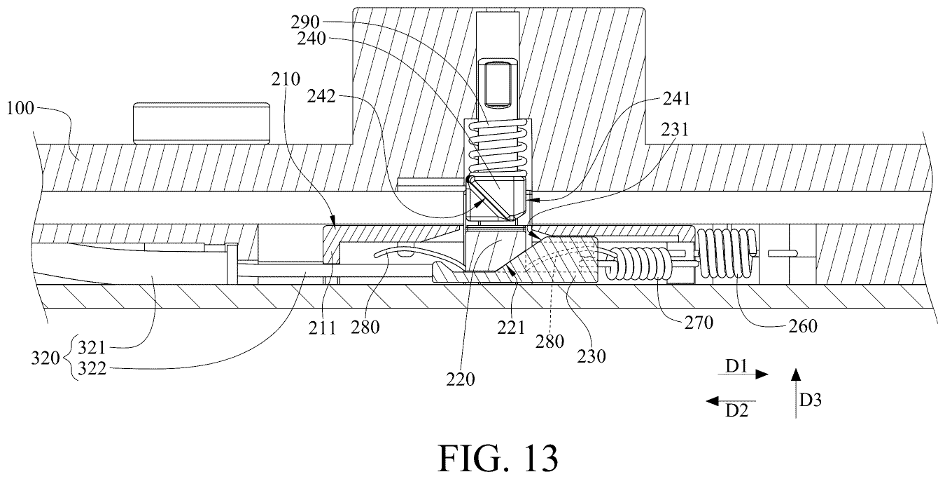

Then, the first return element 260 connected to the guiding element 100 and the sliding element 210 returns the sliding element 210 along the insertion direction D1 with respect to the guiding element 100 to be in a state as shown in FIG. 13. At this time, the removal of the interface card 14 makes no abutting on the blocking element 240, so that the fourth return element 290 disposed between the guiding element 100 and the blocking element 240 can recover from deformation through its flexibility so as to return the blocking element 240 to be in the state as shown in FIG. 13.

Accordingly, the connection between the interface card 14 and the connector 12 can be released simply by operating the trigger assembly 300. Then, the interface card 14 can be removed from the guiding element 100 simply by holding the interface card 14. The interface card 14 is not damaged during its removal, ensuring the reusability of the withdrawn interface card 14.

Also, with the flexibility of the wire 322, the arrangement of the trigger assembly 300 would not be restricted to the adjacent arrangement of the interface card 14, and can be flexibly disposed in any suitable area within the electronic device 1. However, the present disclosure is not limited to the flexibility of the wire 322. In some embodiments of the present disclosure, the trigger assembly may include only one rigid stick as long as there is sufficient space around the interface card for arranging the trigger assembly, and the pushing element can still be moved by pushing or pulling the rigid stick. In some other embodiments of the present disclosure, the trigger assembly may alternatively include a signal transmitting element and a movement element, and the signal transmitting element can wirelessly send a movement signal after receiving a wirelessly transmitted instruction signal for instructing the movement element to move the pushing element.

Further, in some other embodiments of the present disclosure, the second return element can be omitted, and the return movement of the pushing element along the insertion direction with respect to the sliding element can be performed only by the trigger assembly. Furthermore, in some other embodiments of the present disclosure, the third return elements and the fourth return element can be omitted, and the return movements of the lifted element and the blocking element can be performed only by gravity.

Please be noted that the movements of the first return element 260 and the second return element 270 as mentioned above can be achieved by respect adjustment to their elastic restoring forces, but the present disclosure is not limited thereto.

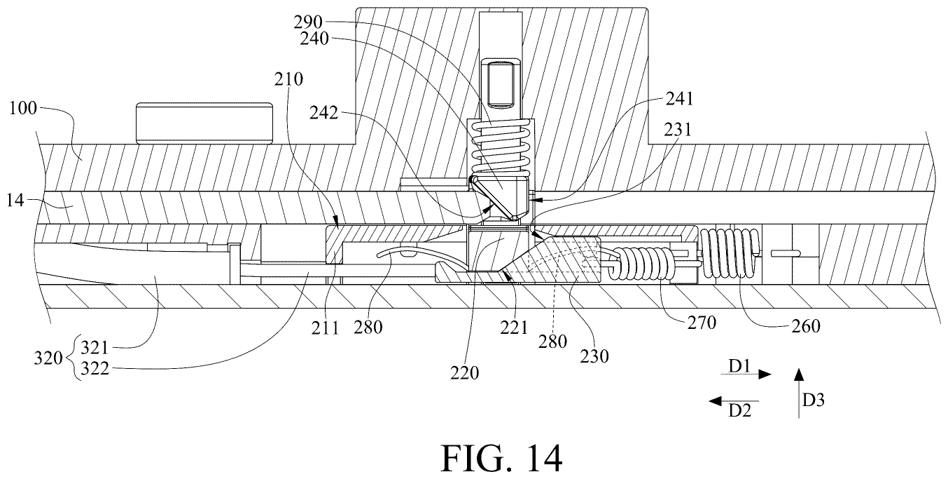

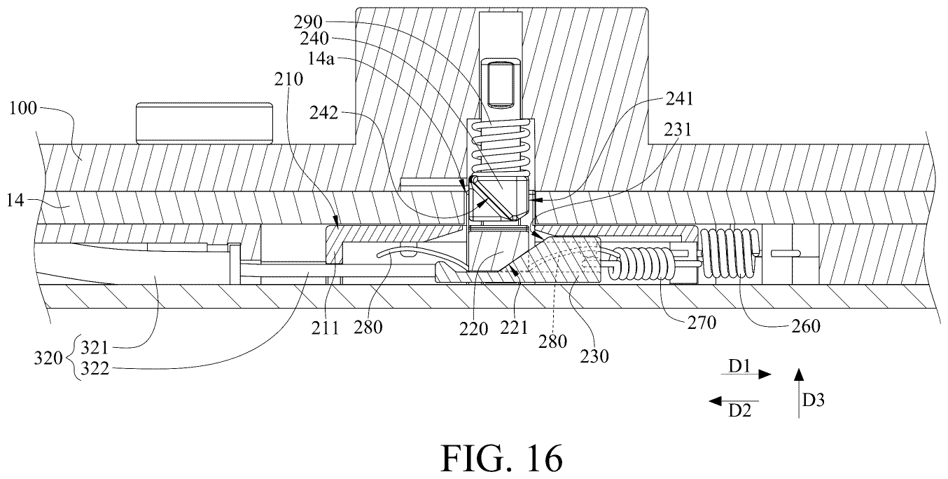

In the following, operation of the electronic device 1 during insertion of the interface card 14 is illustrated. Please refer to FIG. 14 to FIG. 16 with reference to FIG. 1 to FIG. 5, where FIG. 14 to FIG. 16 are partial and cross-sectional views of the electronic device of FIG. 1 during insertion of an interface card.

As shown in FIG. 14, the interface card 14 can be inserted into the guiding element 100 along the insertion direction D1. During the insertion of the interface card 14, the interface card 14 can abut on the inclined abutted surface 242 of the blocking element 240 so as to lift the blocking element 240 along the second direction D3 via the inclined abutted surface 242.

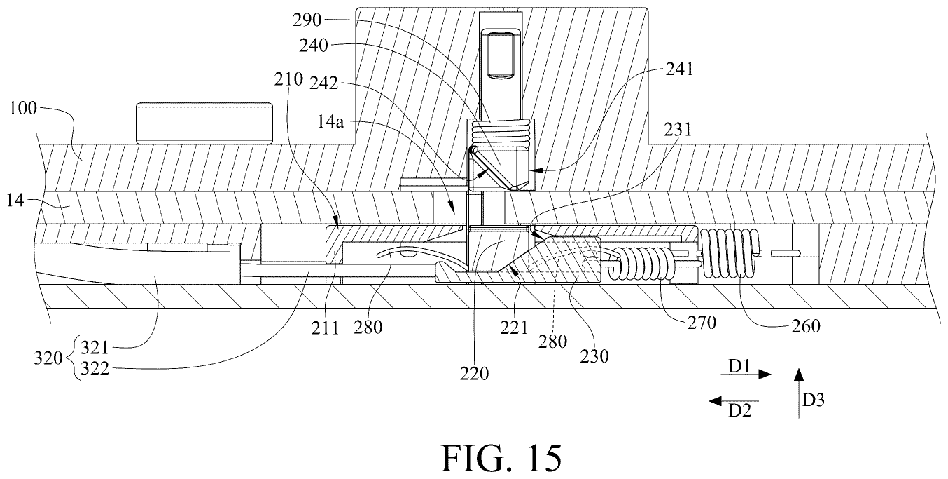

Since the blocking element 240 is lifted away from the insertion path of the interface card 14, the interface card 14 can be continuously moved along the insertion direction D1 from the state shown in FIG. 14 to the state shown in FIG. 15.

Then, when the recess 14a of the interface card 14 is moved to be aligned with the blocking element 240 during the movement of the interface card 14, the fourth return element 290 disposed between the guiding element 100 and the blocking element 240 can recover from deformation through its flexibility so as to return the blocking element 240 to be in the state as shown in FIG. 15. At this time, the blocking element 240 can restrict movement of the interface card 14 along the first direction D2 via the blocking surface 241.

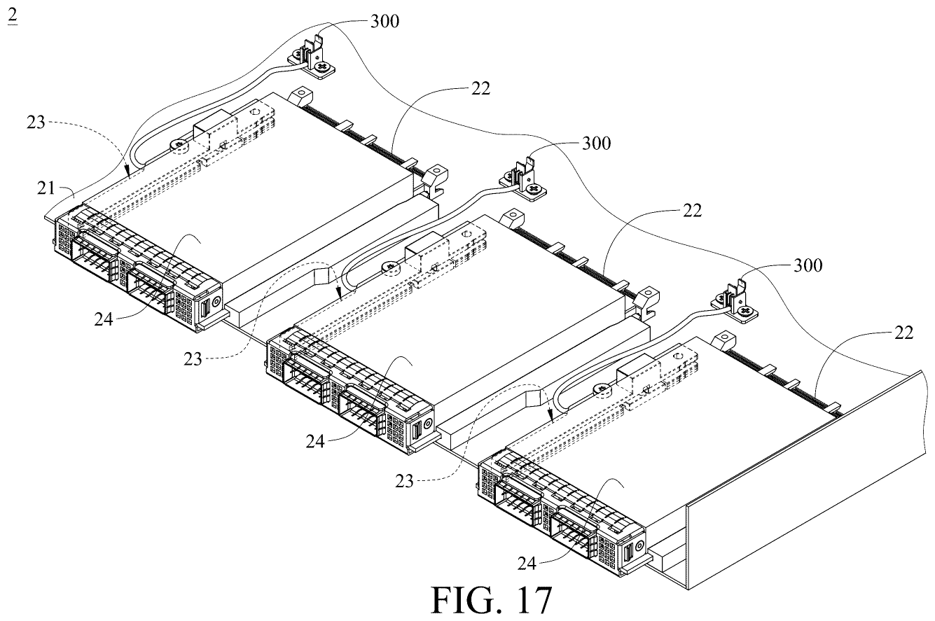

Please refer to FIG. 17, which is a perspective view of an electronic device according to another embodiment of the present disclosure.

An electronic device 2 provided in this embodiment may include a mainboard 21, three connectors 22, three fixing frames 23 and three interface cards 24. Except for the quantities, the mainboard 21, the connectors 22, the fixing frames 23 and the interface cards 24 are similar in structure with the mainboard 11, the connector 12, the fixing frame 13 and the interface card 14 of the abovementioned embodiment, and therefore repeated description would not be provided again.

In the arrangement of three sets of the connectors 22, the fixing frames 23 and the interface cards 24, the connection between one interface card 24 and one connector 22 of each set can be released by operating corresponding trigger assembly 300 of the fixing frame 23, thereby convenient for subsequent process, such as examination, maintenance or replacement of the interface cards 24.

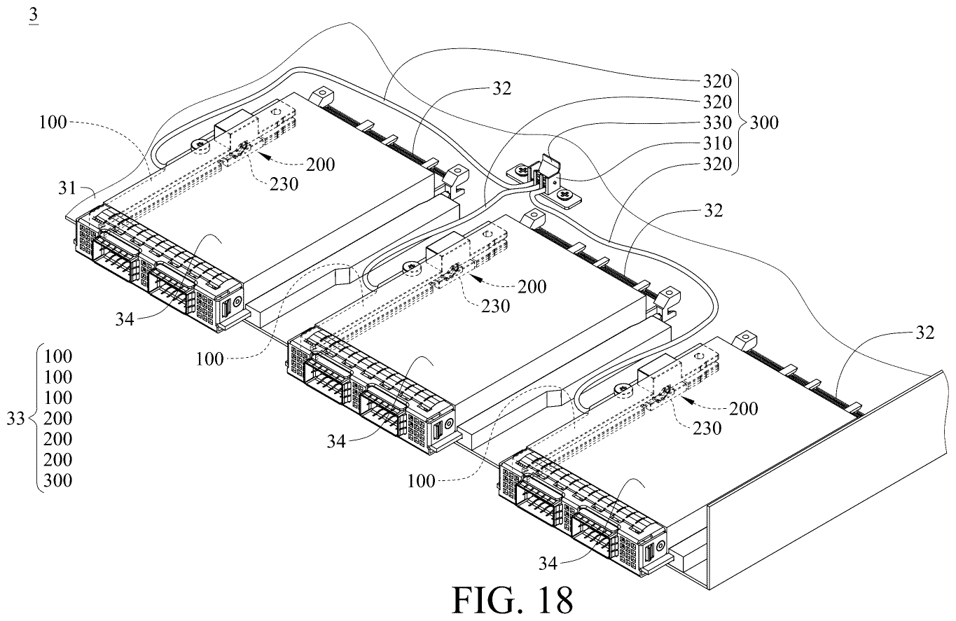

Please refer to FIG. 18, which is a perspective view of an electronic device according to further another embodiment of the present disclosure.

An electronic device 3 provided in this embodiment may include a mainboard 31, three connectors 32, a fixing frame 33 and three interface cards 34. The fixing frame 33 may include three guiding elements 100, three removal assemblies 200 and a trigger assembly 300. The trigger assembly 300 may include a base member 310, three connection members 320 and a pivot member 330. The pivot member 330 can be connected to the connection members 320 to be respectively connected to three pushing elements 230 of the removal assemblies 200 via the connection members 320. Except for the quantities, the mainboard 31, the connectors 32, the fixing frame 33 and the interface cards 34 are similar in structure with the mainboard 11, the connector 12, the fixing frame 13 and the interface card 14 of the abovementioned embodiment, and therefore repeated description would not be provided again.

In the arrangement of one pivot member 330 connected to three pushing elements 230 respectively via three connection members 320, the connections between three interface cards 34 and three connectors 32 can be released simply by operating the trigger assembly 300 once, thereby convenient for subsequent process, such as examination, maintenance or replacement of the interface cards 34.

According to the removal assembly, the fixing frame and the electronic device discussed above, the connection between the interface card and the connector can be released simply by operating the trigger assembly. Then, the interface card can be removed from the guiding element simply by holding the interface card. The interface card is not damaged during its removal, ensuring the reusability of the withdrawn interface card.

Also, with the flexibility of the wire, the arrangement of the trigger assembly would not be restricted to the adjacent arrangement of the interface card, and can be flexibly disposed in any suitable area within the electronic device.

The embodiments are chosen and described in order to best explain the principles of the present disclosure and its practical applications, to thereby enable others skilled in the art best utilize the present disclosure and various embodiments with various modifications as are suited to the particular use being contemplated. It is intended that the scope of the present disclosure is defined by the following claims and their equivalents.

What is claimed is:

1. A removal assembly configured to remove an interface card which is slidably placed into a guiding element, the removal assembly comprising:
a sliding element configured to be movably disposed on the guiding element along a first direction;
a lifted element movably disposed on the sliding element along a second direction different from the first direction; and
a pushing element movably disposed in the sliding element along the first direction so as to selectively move the lifted element into a recess of the interface card.

2. The removal assembly according to claim 1, wherein the sliding element comprises a plurality of first side walls surrounding a horizontal passage, the pushing element is movably disposed in the horizontal passage, and the pushing element selectively pushes one of the plurality of first side walls along the first direction.

3. The removal assembly according to claim 2, wherein the sliding element further comprises a plurality of second side walls protruded from at least one of the plurality of first side walls along the second direction, the plurality of second side walls surround a vertical passage, the lifted element is movably disposed in the vertical passage, the lifted element or the pushing element has at least one inclined guiding surface, and the lifted element moves along the second direction within the vertical passage through guiding of the at least one inclined guiding surface and restriction of the plurality of second side walls during movement of the pushing element along the first direction.

4. The removal assembly according to claim 1, further comprising a first return element connected to the guiding element and the sliding element.

5. A fixing frame configured to fix an interface card, the fixing frame comprising:
a guiding element configured for the interface card to be slidably placed into the guiding element; and
a removal assembly comprising:
a sliding element movably disposed on the guiding element along a first direction;
a lifted element movably disposed on the sliding element along a second direction different from the first direction; and
a pushing element movably disposed in the sliding element along the first direction so as to selectively move the lifted element into a recess of the interface card.

6. The fixing frame according to claim 5, wherein the sliding element comprises a plurality of first side walls surrounding a horizontal passage, the pushing element is movably disposed in the horizontal passage, and the pushing element selectively pushes one of the plurality of first side walls along the first direction.

7. The fixing frame according to claim 6, wherein the sliding element further comprises a plurality of second side walls protruded from at least one of the plurality of first side walls along the second direction, the plurality of second side walls surround a vertical passage, the lifted element is movably disposed in the vertical passage, the lifted element or the pushing element has at least one inclined guiding surface, and the lifted element moves along the second direction within the vertical passage through guiding of the at least one inclined guiding surface and restriction of the plurality of second side walls during movement of the pushing element along the first direction.

8. The fixing frame according to claim 5, further comprising a trigger assembly connected to the pushing element;
wherein the trigger assembly selectively moves the pushing element along the first direction so as to lift the lifted element along the second direction via the pushing element and to push the sliding element along the first direction via the pushing element.

9. The fixing frame according to claim 8, wherein the trigger assembly comprising:
a base member;
a connection member connected to the pushing element; and
a pivot member pivotably disposed on the base member, wherein the pivot member is connected to the connection member so as to selectively move the pushing element via the connection member.

10. The fixing frame according to claim 9, wherein the connection member comprises a sleeve and a wire, the sleeve is sleeved on the wire, two opposite ends of the sleeve respectively abut on the base member and the guiding element, and two opposite ends of the wire are respectively connected to the pivot member and the pushing element.

11. The fixing frame according to claim 5, wherein the removal assembly further comprises a first return element, and the first return element is connected to the guiding element and the sliding element.

12. The fixing frame according to claim 5, further comprising a blocking element movably disposed on the guiding element along the second direction, wherein the blocking element has a blocking surface and an inclined abutted surface, a normal direction of the blocking surface is opposite to the first direction, and the inclined abutted surface faces away from the blocking surface.

13. An electronic device comprising:
a mainboard;
a connector disposed on the mainboard;
a fixing frame located on a side of the connector, the fixing frame comprising:
a guiding element; and
a removal assembly comprising:
a sliding element movably disposed on the guiding element along a first direction;
a lifted element movably disposed on the sliding element along a second direction different from the first direction; and
a pushing element movably disposed in the sliding element along the first direction; and
an interface card slidably placed into the guiding element and detachably connected to the connector;
wherein the pushing element selectively moves along the first direction so as to move the lifted element into a recess of the interface card.

14. The electronic device according to claim 13, wherein the sliding element comprises a plurality of first side walls surrounding a horizontal passage, the pushing element movably disposed in the horizontal passage, and the pushing element selectively pushes one of the plurality of first side walls along the first direction.

15. The electronic device according to claim 14, wherein the sliding element further comprises a plurality of second side walls protruded from at least one of the plurality of first side walls along the second direction, the plurality of second side walls surround a vertical passage, the lifted element movably disposed in the vertical passage, the lifted element or the pushing element has at least one inclined guiding surface, and the lifted element moves along the second direction within the vertical passage through guiding of the at least one inclined guiding surface and restriction of the plurality of second side walls.

16. The electronic device according to claim 13, wherein the fixing frame further comprises a trigger assembly connected to the pushing element;
wherein the trigger assembly selectively moves the pushing element along the first direction so as to lift the lifted element along the second direction via the pushing element and to push the sliding element along the first direction via the pushing element.

17. The electronic device according to claim 16, wherein the trigger assembly comprises:
a base member;
a connection member connected to the pushing element; and
a pivot member pivotably disposed on the base member, wherein the pivot member is connected to the connection member so as to selectively move the pushing element via the connection member.

18. The electronic device according to claim 17, wherein the connection member comprises a sleeve and a wire, the sleeve is sleeved on the wire, two opposite ends of the sleeve respectively abut on the base member and the guiding element, and two opposite ends of the wire are respectively connected to the pivot member and the pushing element.

19. The electronic device according to claim 13, wherein the removal assembly further comprises a first return element connected to the guiding element and the sliding element.

20. The electronic device according to claim 13, further comprising a blocking element movably disposed on the guiding element along the second direction, wherein the blocking element has a blocking surface and an inclined abutted surface, a normal direction of the blocking surface is opposite to the first direction, and the inclined abutted surface faces away from the blocking surface.
